(19) United States
(12) Patent Application Publication
(10) Pub. No.: US 2025/0065401 A1
(43) Pub. Date: Feb. 27, 2025

(54) HIGH THROUGHPUT ADDITIVELY MANUFACTURED COOLING DEVICES

(71) Applicant: The Research Foundation for the State University of New York, Binghamton, NY (US)

(72) Inventors: Scott N. Schiffres, Binghamton, NY (US); Arad Azizi, Binghamton, NY (US)

(21) Appl. No.: 18/814,929

(22) Filed: Aug. 26, 2024

Related U.S. Application Data
(60) Provisional application No. 63/534,648, filed on Aug. 25, 2023.

(51) Int. Cl. B22F 7/08; B22F 10/14; B29C 64/118; B29L 31/34; B33Y 10/00; B33Y 80/00; H05K 7/20

(52) U.S. Cl. CPC B22F 7/08; B33Y 10/00; B33Y 80/00; H05K 7/2039; B22F 10/14; B29C 64/118; B29L 2031/34

(57) ABSTRACT

A cooling device for electronics created ed by additive manufacturing directly on the surface of an electronic device, the colling device created by processes such as controlled focused energy of laser or electron beam, stereolithography, or fused deposition modeling. The cooling device is especially useful in being placed next to or packaged with high-power electronic chips requiring significant heat dissipation.

### CROSS-REFERENCE TO RELATED APPLICATION

This application claims the benefit of U.S. Provisional Patent Application No. 63/534,648, filed on Aug. 25, 2023, the entirety of which is hereby incorporated herein by this reference.

### BACKGROUND OF THE INVENTION

### 1. Field of the Invention

The present invention generally relates to the field of additive manufacturing. More particularly, the present invention relates to additively manufactured cooling devices that are placed on or packaged with electronic devices, lids and or heat spreaders and dissipators.

### 2. Description of the Related Art

Power consumed by the operation of semiconductor devices creates a significant amount of heat, which must be removed from the device. The heat fluxes in electronic chips, especially the ones used in data centers, are increasing drastically every year with maximum thermal design powers (TDPs) of 350 W for CPUs and 750 for GPUs. To remove heat is critical, but doing this efficiently is a growing challenge.

Only three processes govern the transfer of heat: conduction, convection, and radiation. Basically, conduction applies to solids, convection to liquids and gases, and radiation to vacuums, of which there are very few in a semiconductor. There's production, conduction, and dissipation. In essence, the chip produced the heat, the heat is conducted it out to somewhere, and then dissipated. Conduction and dissipation is a physical analysis that includes fluidics.

One method of conduction and dissipation is simply to put a large heatsink on the semiconductor device. However, there are several problems with the use of a physical heatsink. Getting the cooling optimal requires consideration for air flow and the mechanical design of the space in which it resides so that the impact on other devices is considered. Furthermore, hotspots on the semiconductor device can occur that still damage the device.

Another method of cooling such chips is via two-phase liquid immersion or forced liquid convection cooling. In this system, part of the package (the chip itself) or the entire server (chip with motherboard and components) comes into contact with a liquid. With many dielectric fluids, the chip cools down via boiling heat transfer.

Also in use for boiling heat transfer are plates with boiling enhancement coatings (sintered copper) that are used for such configurations as heat sinks. However, before the heat reaches the surface of the boiling enhancement plate, it has to pass a thermal interface material (TIM) 1, internal heat spreader (IHS), and TIM 2, which adds to thermal resistance. There is not much freedom of design in such boiling enhancement plates due to their current manufacturing method. Moreover, thermal interfaces increase overall thermal resistances

The design of the cooling system for a semiconductor device is often a suboptimal tradeoff between performance and potential operational limitations. It is accordingly to a better heat conduction and dissipation device to assist in cooling semiconductor devices that the present invention is primarily directed.

### BRIEF SUMMARY OF THE INVENTION

Briefly described, the present invention is directed to additive manufacturing (e.g. by controlled focused energy of laser or electron beam [L-PBF, EB-PBF], stereolithography [SLA], fused deposition modeling [FDM]) to fabricate a cooling device or feature on an electronic device that generates heat in operation. The present inventive method is scalable to high-throughput mass production alongside the production of electronic devices. The present invention includes systems and methods that make conventional heatsinks and lids that are more economical per unit volume than current additively manufactured products.

In particular, conventional lids for electronic devices have smooth mating surfaces to silicon chips. Many OEM processor manufacturers sell electrical devices with lids already in place. These lids serve multiple purposes: hermetic sealing, electromagnetic interference reduction, thermal heat spreading, oxygen and humidity barriers. They also serve a mechanical purpose, to stiffen and prevent flexing induced failure of the electronic devices and interconnects.

The use of additive manufacturing here allows designs of cooling devices with higher surface areas. These higher surface areas can take the form of lattices, gyroids, and other high-surface area forms that vary spatially. For instance, fractal-like cold plate designs can be optimized for hotspots with various densities across the silicon or IHS.

In one embodiment, the invention includes a method of packaging a cooling device with an electronic device by abrading a surface of an electronic device, where the electronic device is operable to produce heat that is thermally rejected from the surface. Then a cooling device is additively formed on the abraded surface of the electronic device. Alternatively, the surface can be planarized by fly-cutting end milling, or other subtractive processes. The cooling device can be formed by laser powder bed fusion, or with a metal-polymer composite that is post-processed into metal through a binder removal and sintering process. The surface of the electronic device here can be considered the metal lid and hermetic seal, or if no lid, then the surface of the chip package.

Further, the forming can be made by ultrasonic additive manufacturing. A low melting layer can be incorporating in the cooling device. And the forming of the cooling device can be with with one or more of Cu, Ag, Al, or alloys thereof.

The system can be embodied as forming of the cooling device can be forming a polymeric manifold system on the surface of the cooling device. And the polymeric manifold system can be formed by fused deposition modeling.

In another embodiment, the invention includes an electronics package that has an electronic device operable to produce heat, with the electronic device having a surface thereof configured to thermally radiate heat, and the surface is further abraded. There is a cooling device additively formed on the abraded surface of the electronic device.

In a further embodiment, the invention is a cooling device having body that has a surface thereof, with the body further attached to an abraded surface of an electronic device. The body is configured to thermally reject heat from the surface of the body and is formed from an additive manufacturing process.

The additive printing of cooling devices directly onto these lids incorporates provides several advantages: (1) it gives the benefits of additive manufacturing in the manufacturing process; (2) it does not unduly affect the reliability of conventionally packaged devices; and (3) it eliminates the need to post-machine a printed design on the electronics package. Further, the benefits of additive manufacturing for cooling devices includes free-form designs with lattices, high surface area, integrated wicks. The present technology provides more efficient cooling of the electronic chip by reducing thermal resistances in addition to innovative designs for boiling enhancement via hybrid additive manufacturing techniques. It is these and other advantages and benefits as would be known to one of skill in the art that the present invention provides over the prior art.

### BRIEF DESCRIPTION OF THE DRAWINGS

FIG. 1 is a schematic diagram illustrating one embodiment of the process steps of the present invention.

FIG. 2 is an image of a directly printed cooling device on a packaged device using a tight tolerance picture frame build plate insert.

FIG. 3A is a diagram of an abrading/planarizing a lid/chip surface for subsequent printing onto it.

FIG. 3B is a diagram of mounting multiple lids or chips in one build plate.

FIG. 4 is a diagram of recoating of the surface of an electronic device that can occur prior to fusion or deposition of a metal-infused polymer.

FIG. 5A is a diagram of a directly printed heatsink in a single-phase flow setup used to cool a microprocessor.

FIG. 5B is a diagram of a printed polymeric manifold directly on metal cooling features of chip or chip underlying substrate.

FIG. 5C is a diagram of a printed polymeric manifold directly on metal cooling features of lid.

FIG. 6 is a picture of a printed polymer manifold directly attached to a processor.

FIG. 7 is an image of a printed metal heatsink directly on chip.

### DETAILED DESCRIPTION OF THE INVENTION

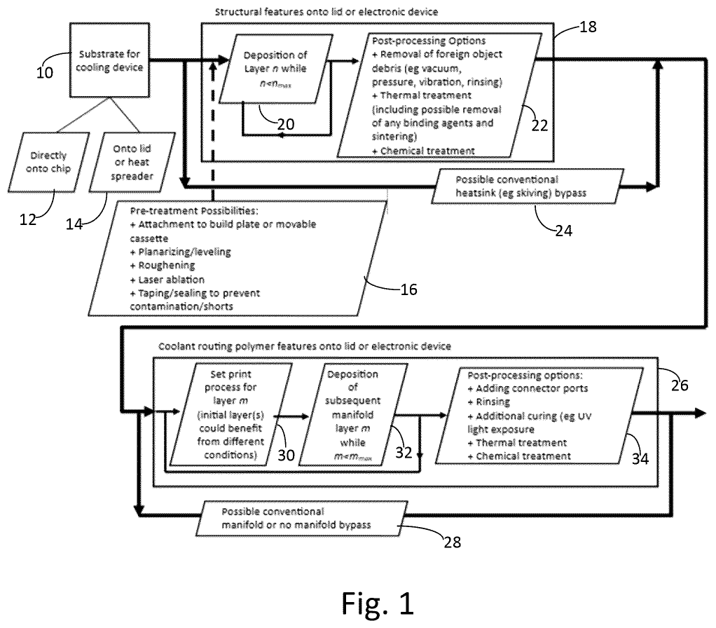

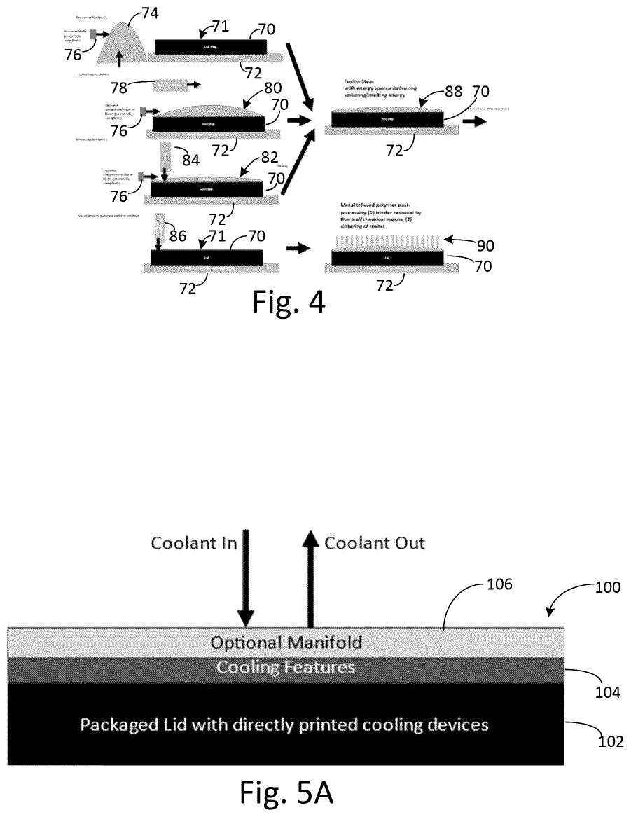

With reference to the figures in which like numerals represent like elements throughout the several views, FIG. 1 is a schematic illustrating the elements of the one embodiment of the process of the invention. The invention can have elements related to structural features onto lid or electronic device, and/or coolant routing polymer features onto lid or electronic device. A substrate is provided for a cooling device 90 (FIG. 4) as shown at step 10. The additive process can then be directed directly on the chip, step 12 or onto the lid or heat spreader of the chip, step 14. The process can have a convention heatsink made on the substrate, as shown at step 24, or otherwise the structural feature of the cooling device 90 can be printed on the lid or directly on the electronic device 90, as shown at process 18.

In process 18, the deposition of the layers commences, as shown at process 20. There are potential pretreatments of the surface possible, as shown at preprocess 16, which includes act of abrasion, such as ablation, planarizing, roughing, etc. Then after the deposition of layers at process 20, there can be post-processing of the printing, as shown at process 22. The post-processing can include cleaning, removal of debris, chemical treatment, etc.

In this embodiment, after the printing of structural features on the lid at process 18, or after fabrication of a conventional heatsink at step 24, then the process of using cooler to route polymer features on the surface, as shown at process 26. Alternately a conventional manifold (or no manifold) can be integrated onto the electronic device 80 and the process moves forward, as shown at step 28. Otherwise, in process 26, the print process is set for initial layers, step 30, and then the deposition of the layers of the manifold commences at step 32. Steps 30 and 32 can also be bypassed to step 34. At step 34, the post-processing of the polymer features occurs, such adding ports, rinsing, curing, chemical treatment, etc.

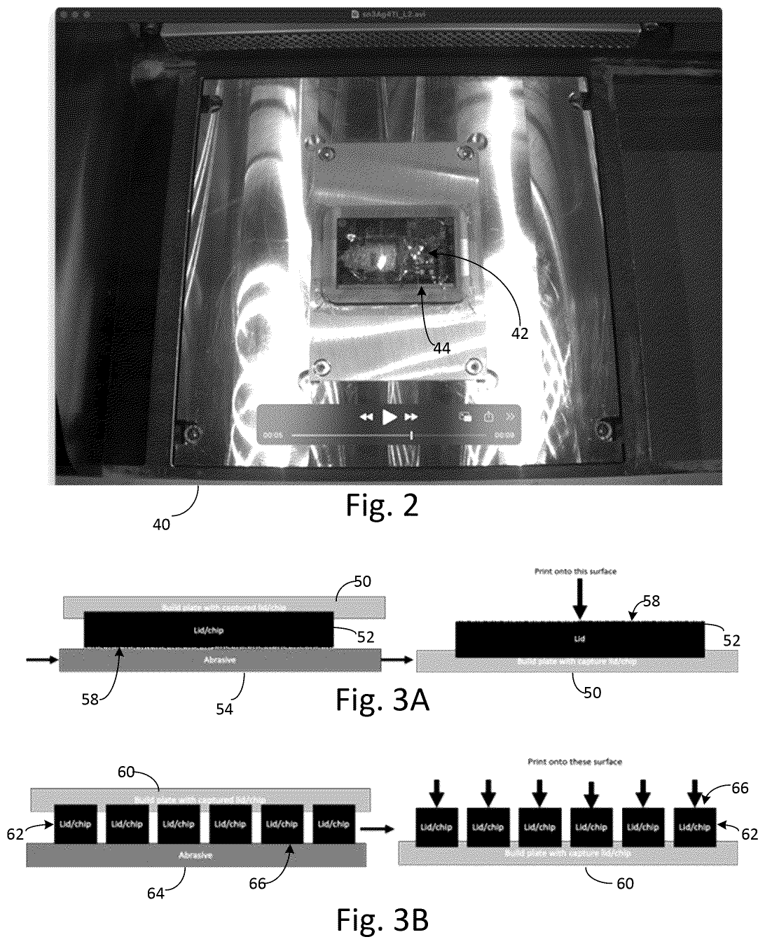

FIG. 2 is an image 40 of a directly printed cooling device 42 on a packaged device 44 using a tight tolerance picture frame build plate insert. The benefit of using conventional lids/integrated heat spreaders (IHS) is that printing onto the lids/IHS will not negatively impact reliability, while obtaining the benefits of additively manufactured features. This printing onto the lid/IHS will also allow lateral heat spreading. Most designs printed onto the lid will not significantly modify the stiffness and curvature of the lid. Moreover, not having a second TIM (TIM2) will remove multiple failure modes (i.e. non-uniform TIM deposition or compression, and material compatibility with dielectric fluids), and better cooling also leads to better reliability.

The as shown in FIG. 2, the invention includes an electronics package (packaged device 44) that has an electronic device (such as a processor) operable to produce heat, with the electronic device (lid/chip 52; FIG. 3A) having a surface 58 thereof configured to thermally radiate heat, and the surface is further abraded (abraded surface 58). There is a cooling device, such as cooing device 90 in FIG. 4, additively formed on the abraded surface 58 of the electronic device.

FIG. 3A is a diagram of an abrading lid/chip 52 surface 58, and subsequent printing onto it. Lid/chip 52 is attached to a build plate 50 and an abrasive plate 54 is rubbed against the surface 58 of the lid/chip 52. The printing (additive manufacture) then occurs on the abraded surface 58.

The lid or devices (lid/chip 58) to be printed on can benefit from roughening, which improves the uniform deposition of powder onto the lid surface. This roughening helps to retain powder and prevent powder misfeeding. The roughening step can be skipped if the lid is already rough, but it may still be beneficial for helping to reveal a clean and less oxidized surface. Abrading can use 250 and then 400 SiC wet sanding to roughen the surface and to remove any protective layer (e.g. Nickel). Other methods of roughening may include mechanical forming (e.g. machining, pressing), laser-processing (e.g. laser-ablation), chemical material removal (e.g. etching), and chemical (e.g. electrical, electroless) deposition techniques.

FIG. 3B is a diagram of mounting multiple lids/chips 62 on one build plate 60. The lid/chips 62 are attached to a build plate 60 and an abrasive plate 64 is rubbed against the surfaces 66 of the lid/chips 62. The printing (additive manufacture) then occurs on the abraded surfaces 66. To scale this technology, printing onto multiple lids or semiconductor devices must be printed at once. However, they are typically not flat enough to recoat with conventional recoater designs simultaneously. This can be handled by abrading or machining the lids or devices in a fixture to planarize them. This leveling is particularly important for heterogeneously integrated chip packages that have multiple chips that are non-planar owing to the residual stresses from packaging processing. These chips could even be different heights. Then this fixture can be bolted into the additive manufacturing printer as the buildplate for various metal additive printing technologies (laser powder bed fusion, electron beam powder bed fusion, directed energy deposition, wire-printing, ultrasonic printing, stir friction welding, metal-polymer hybrid, spray coating). In addition to leveling, the abrading step also helps retain powder on the lid surface during recoating.

One benefit of printing a monolithic spreader is relatively lower than a printed heatsink on a conventionally manufactured lid because metal printed material is more expensive, generally slightly lower thermal conductivity, and generally higher roughness than conventional designs. The alternative, a fully printed heatsink would require machining of the heatsink-chip interfacing surface. The current invention eliminates the need for most post-processing, which is a benefit. This invention uses additively manufactured material where it is of greatest benefit, which is more economical and better performing.

FIG. 4 is a diagram of recoating a surface 71 of a lid/chip 70 that can occur prior to fusion, or metal-infused polymer can form a green part that is then debinded and sintered. Several embodiments are shown in FIG. 4. In one embodiment of recoating, the lid/chip 70 is bound to build plate 72. There is a powder reservoir 74 adjacent to the lid/chip 70 and a blade 76 (or roller) then moves the powder over the surface 71 of the lid/chip 70.

Alternately, a powder duster 78 can be used, with or without a roller or blade 76, to place a coating of powder on surface 71. A blade 76 or other cuing device can be used in the embodiment. In another embodiment, a metallic or polymeric paste 82 layer can be applied from a paste dispenser 84 to make a coating of paste on the surface of the chip/lid 70. A blade 76 or roller can also be used to form an even layer or structure on the surface 71 of the lid/chip 70. In a further embodiment, a metal-infused polymer can be deposited from a sprayer 86 via sputter, spray or other physical deposition process on the surface 71 of the chip/lid 70.

The recoater being soft (brushed or silicone) helps print fine features, like lattices. An alternative powder deposition mechanism, i.e. powder dusting, can be used which does not have traditional blade-like recoating mechanism. In such system, powder is deposited onto the lid or semiconductor device using a powder nozzle and a jet stream. The thickness of the powder deposited is software-controlled and can vary based on the design and component heights on the electronic package.

After deposition of the layer of each process, the formed layer 88 can be cured, dried or otherwise processed to attach or additively form a cooling device 90 on the surface 71 of the chip/lid 70. The cooling device 90 in FIG. 4 is embodied as a body with a series of vertically oriented conductive fins. The colling device 90 can be post-processed with a binder removal from chemical or thermal means, or can be sintered in place.

Accordingly, the present technology also applies to printing directly onto the surface of an electronic substrate/chip post-manufacture and packaging. Technologies exist to print directly onto the lid, but this technology also addresses the scaling of this technology to many chips in a high-throughput manner for production environment.

The printing of a powder onto the lid or device requires applying a thin layer of powder onto the lid or device, fusing the powder with a specific geometry or pattern using an energy source, and repeating as needed to make the design. The spatially applied energy source is varied to achieve variable porosity. The feedstock powder can be tuned to achieve porosity, as desired. For instance, certain layers, or spatial positions can use different diameter powders.

An alternative embodiment of this invention prints continuously or semi-continuously, rather than batched in one printer. This can be done where a conveyor brings each lid or chip to a recoating step and then to a laser exposure step. This sample can be fused by an energy source (e.g. laser) in the same position as the recoating, or in a separate space. The lids can convey back and forth between recoater station and fusing region, or they can move between multiple powder deposition and laser fusing stations that alternate depositing powder and exposing. At end of the process, a powder removal step that uses a cleaning mechanism to remove traces of powder can be implemented. This may be via vacuums, gas jetting, compressed and/or liquid cleansing, or chemical processing.

The recoating can alternatively be done at the same location as the laser exposure, so the recoater moves over the build area. The recoating step is then done via a recoater blade. The pressure applied by the recoater blade directly affects the density of the metal powder deposited. The recoater blade should be offset a consistent distance from the printed lid surface, which can be done by various means (e.g. roller on side of lid that sets offset, optical sensing). Alternative embodiments to the recoater blade powder deposition can include powder dusting, followed optionally by compacting (e.g. via roller).

The fixturing device can use a tight tolerance fit, and print on an already packaged device (example shown in FIG. 2). Alternatively, the part can be retained via suction or mechanical fixturing mechanism. Tape or gaskets can be used to seal powder from infiltrating into electrical connections.

The printed parts can be used as is. However, loose metal material may lead to fouling of pumps, narrow channels, so the part may benefit from post-processing to remove loose powder. The post-processing can include a rinse, ultrasonic bath, compressed air, media blasting, immersion of the component in a dielectric liquid bath, chemical processing. Vacuuming and pressurized air and/or fluids can help clean any residue from the print.

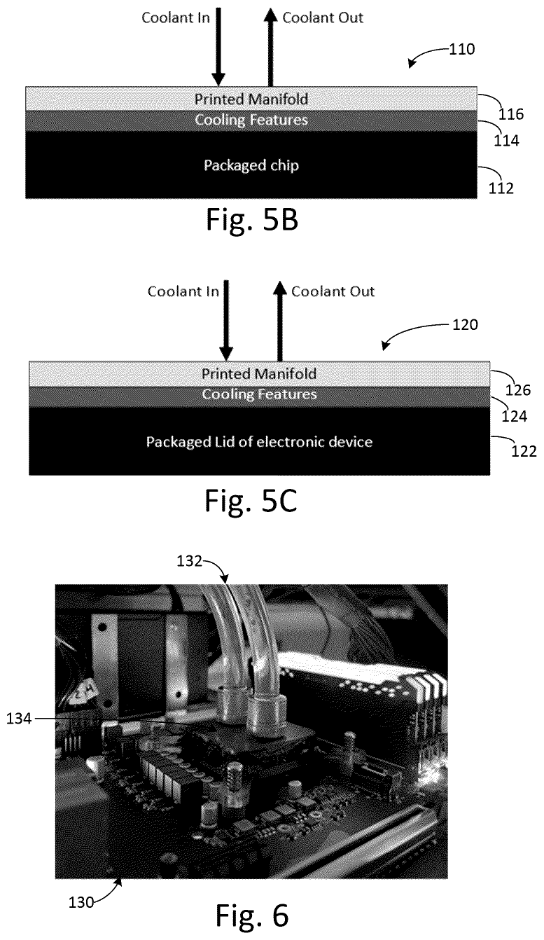

FIG. 5A is a diagram of one embodiment of a directly printed heatsink 100 in a single-phase flow setup used to cool a microprocessor. The coolant will be cooled with heat exchanger (not shown) to ambient or a chiller. On a packaged lid 102, one or more cooling features 104 (device) are printed and there can be an optional manifold 106 to fully and efficiently interface and cool the electronic device.

FIG. 5B is a diagram of an embodiment of heatsink 110 with a printed polymeric manifold 116 directly on metal cooling features 114 on the package chip 112 (or chip underlying substrate). The coolant will be cooled with heat exchanger (not shown) to ambient or a chiller. Adhesion can be made directly to cooling features 114 or underlying lid/polymeric substrate (package chip 112). This removes the need for an o-ring.

FIG. 5C is a diagram of a heatsink 120 with a printed polymeric manifold 126 directly on metal cooling features 124 of lid 122. The coolant will be cooled with heat exchanger (not shown) to ambient or a chiller. Once again, adhesion can be made directly to cooling features 124 or underlying lid/polymeric substrate on package chip 112. This removes the need for an o-ring

FIG. 6 is a picture 130 of a printed polymer manifold 134 directly attached to processor. The printed polymer manifold 134 is directly attached to processor (not visible). Liquid inlet and outlets 132 distributes coolant to the package in one of the manners illustrated in FIGS. 5A-5C.

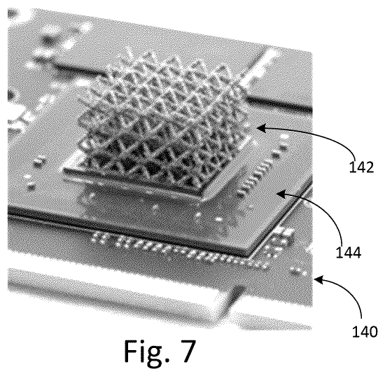

FIG. 7 is an image 140 of a printed metal heatsink 142 directly on chip 144. The body of the heatsink 142 is comprise of printed lattices. The printing of lattices onto a bare silicon chip is expected to have a ˜2× higher maximum heat flux than the bare silicon chip in a two-phase immersion cooling test for a ˜1 cm2 chip at 95 W TDP. These printed designs also have lower thermal resistance by ˜20%.

The design of the heatsink on the lid can take various forms, including fractal-like, thin film of variable porosity, or wick and lattice, or lattice with porous wick exterior. The designs are dependent on the method of cooling (forced convection single-phase or two-phase, pool boiling, air cooled, etc).

The wicks porosity can be tuned by changing the energy processing and varying the particle size. In particular, the energy density is tuned by laser power, laser scanning speed, laser spot size (varied by focus and focal distances), raster pattern, raster overlap, raster strategies. At lower powers or at the exterior surface, powders will not be fully consolidated. The capillary pressure will be controlled by the narrowness of gaps between particles, which is a function of particle size.

Smaller particles will have high capillary driving pressure but also lower permeability (resulting in higher pressure drops). These are competing effects: smaller particles have bigger driving pressures but also have greater pressure drop for the same flow rate. Secondary effects of thermal conductivity versus particle size and contact area also exist. By printing with varying energy densities, different degrees of porosity can be affected spatially (similar to biporous wicks for heat pipes). By controlling the porosity spatially, regions of high porosity, that act like arteries, can feed progressively narrower capillaries. Advanced recoating systems can also be used to deposit multiple powder sizes spatially.

In one embodiment, the invention includes a method of packaging a cooling device 90 with an electronic device by abrading a surface of an electronic device, where the electronic device, such as a processor, is operable to produce heat that is thermally rejected from the surface, e.g. surface 58. Then a cooling device 90 is additively formed on the abraded surface 58 of the electronic device. The cooling device 90 can be formed by laser powder bed fusion, or with a metal-polymer composite that is post-processed into metal through a binder removal and sintering process, as is further described herein.

Further, the forming can be made by ultrasonic additive manufacturing. As shown in FIG. 4, a low melting layer such as formed layer 88 can be incorporated in the cooling device 90. And the forming of the cooling device can be with one or more of Cu, Ag, Al, or alloys thereof, as described herein.

The system can be embodied with forming a polymeric manifold system (printed manifold 116) on the surface 71 of the cooling device (lid/chip 70). And the polymeric manifold system can be formed by fused deposition modeling.

The printed heat spreading material should be of high thermal conductivity, as that extends the useful length of a fin. Metals, like copper (CU), silver (Ag), and aluminum (Al) are of greatest interest. While silver is slightly higher thermal conductivity than copper (˜3-7% depending on processing), its cost differential makes copper of greater commercial interest. High thermal conductivity composites (e.g. metal with diamond) are also of potential interest.

The printed design can be a uniform initial layer to improve boiling at the surface of the lid/heat spreader or chip over the entire surface and then fins of a height that utilizes the material efficiently (e.g. fin tip is still significantly above the temperature of the free fluid). Subsequent layers can benefit from exterior porosity/roughness to enhance boiling, if the cooling mode is two-phase (e.g. boiling or evaporation). Boiling enhanced fins and single-phase forced liquid convection don't need to be very tall, owing to the high heat transfer coefficient relative to air forced convection. One key aspect is improving the thermal contact to the substrate.

The invention in some implementations may also use high-fluence laser (e.g. nanosecond to femtosecond pulses) to ablate material to create boiling nucleation sites. These nucleation sites can trap vapor, so to also reduce superheating required to initiate boiling. These holes can serve as re-entrant cavities for two-phase boiling.

In some implementations, after the additive manufacturing and cleaning processes is complete, another step of material deposition might be performed by other means such as chemical electrodeposition or room-temperature sintering to modify the printed material (e.g., porosity, surface area and surface roughness of the additively formed structures).

In some implementations, the deposition will occur as an intermediate state (eg polymer-metal composite), and then be thermally postprocessed into a metal solid. This process requires higher temperatures, and will impart greater thermal stress and melt conventional solders, so would be most applicable to printing onto the lid that is unpackaged, as the processing would damage a packaged silicon chip. This intermediate state could also be additively manufactured with the lid as an insert and then polymer-metal composite injection into a cavity.

In some implementations, the printed features will serve as electronic connections onto the lid. These electronic connections include power electronic leads or antenna arrays. The electrical connections can serve as electrical purposes and as thermal heatsinks. For instance, a ground plate also serving as a wick, or antennas also serving as fins.

In some implementations, a manifold 126 can be attached to the heat spreader or boiling enhancement structure for fluid delivery and extraction, such as in FIGS. 5A-5C. This manifold can be printed or made conventionally. The manifold can be printed in some applications directly onto the lid, chip or chip package, or made separately (additively or conventionally) and bonded via adhesives or sealed by an o-ring or gasket. The same casettes/build platforms used in the earlier part of this invention can be used to print directly onto the lids or devices, so planarity is already known for the polymer processing. The polymer processing can use a light-cured polymer or thermal plastics or epoxy type polymers.

In using a laser cured polymer, the lids or device can be submerged in a vat. A light can cure polymer selectively in space. The curing step can occur while in the vat. The first layer may benefit from different processing than subsequent layers. The wick may be hard to seal against, so a perimeter of the cooling manifold should be made against a relatively non-porous surface. This printing will be able to handle z-height protrusions of the textured cooling device that protrudes beyond the plane of the seal. This will require some compensation in the initial printed manifold layers. The printed manifold and any substrate that its bonded to have the non-cured polymers rinsed out by a liquid. Any support material can be removed. Additional polymer curing (cross-linking) can occur via a UV light source, as needed.

Fused deposition can also be used to produce polymer manifolds. The g-code should be developed to consider the extruder size so it does not crash into the printed cooling structures previously deposited. The deposition of the FDM part must consider thermal stress and overhangs more than SLA, and also has generally coarser resolution, so could be less desirable.

The manifold material must be compatible with the refrigerant or dielectric liquid used. This can be tested by swelling and weight gain of the polymer in the refrigerant, mechanical testing and permeation testing. It can also be assessed by the rate at which a container made of a material of question loses refrigerant or dielectric liquid. The addition of elements to the polymer, like BN, or additional metallization, by evaporation or sputtering or electroless electroplating, might help reduce leakage rates.

In some implementations the manifolds can be printed and attached by an adhesive, but direct printing of the manifolds offers potential benefits in terms of tighter sealing. It also diminishes the need for an o-ring which are potential leakage points.

For implementations on lids of chips, in some implementations the lid can be printed post installation onto the chip package, while in other implementations the lid can be printed prior to lid mounting. Printing prior to mounting lid is beneficial at highest scale production, but if chips are already lidded, and done at low to moderate scales, there may be efficiencies in leaving the lid attached to the chip.

In implementations that are printed onto chips directly, in most implementations, the chip will be processed for heat removal surface area enhancements and/or boiling enhancements post-packaging. However, in some implementations, it may be beneficial to print these structures prior to packaging or at an intermediate stage of packaging.

The corresponding structures, materials, acts, and equivalents of all means or step plus function elements in the claims below, if any, are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of one or more aspects of the invention and the practical application, and to enable others of ordinary skill in the art to understand one or more aspects of the invention for various embodiments with various modifications as are suited to the particular use contemplated.

What is claimed is:

1. A method of packaging a cooling device with an electronic device, comprising:
planarizing a surface of an electronic device, the electronic device operable to produce heat that is thermally rejected from the surface; and
additively forming a cooling device on the planarized surface of the electronic device.

2. The method of claim 1, wherein the cooling device is formed by laser powder bed fusion.

3. The method of claim 2, wherein the forming is made by a metal-polymer composite that is post-processed into metal through a binder removal and sintering process.

4. The method of claim 1, wherein the forming is further made by ultrasonic additive manufacturing.

5. The method of claim 1, further incorporating a low melting interlayer in the cooling device.

6. The method of claim 1, wherein forming the cooling device is forming the cooling device with one or more of Cu, Ag, Al, or alloys thereof.

7. The method of claim 1, wherein forming the cooling device is forming a polymeric manifold system on the surface of the cooling device.

8. The method of claim 7, wherein forming the polymeric manifold system is forming by fused deposition modeling.

9. The method of claim 7, wherein forming the polymeric manifold system is forming with a UV-cured polymer.

10. An electronics package, comprising:
an electronic device operable to produce heat, the electronic device having a surface thereof configured to thermally reject heat, and the surface further planarized; and
a cooling device additively forming on the planarized surface of the electronic device.

11. The electronics package of claim 10, wherein the cooling device is formed by laser powder bed fusion.

12. The electronics package of claim 11, wherein the cooling device is formed by a metal-polymer composite that is post-processed into metal through a binder removal and sintering process.

13. The electronics package of claim 10, wherein the cooling device is formed by ultrasonic additive manufacturing.

14. The electronics package of claim 10, wherein in the cooling device includes a low melting interlayer.

15. The electronics package of claim 10, wherein the cooling device is formed with one or more of Cu, Ag, Al, or alloys thereof.

16. The electronics package of claim 10, wherein the cooling device is a polymeric manifold system formed on the surface of the cooling device.

17. The electronics package of claim 16, wherein the polymeric manifold system is formed by fused deposition modeling.

18. The electronics package of claim 16, wherein the polymeric manifold system is formed with a UV-cured polymer.

19. A cooling device, comprising a body that has a surface thereof, the body further:
attached to an planarized surface of an electronic device;
configured to thermally rejected heat from the surface of the body; and
formed from an additive process.

20. The cooling device of claim 19, wherein the body of the cooling device is formed with one or more of Cu, Ag, Al, or alloys thereof.
